(19) United States
(12) Patent Application Publication
(10) Pub. No.: US 2023/0284382 A1
(43) Pub. Date: Sep. 7, 2023

(54) SEMICONDUCTOR DEVICE, ELECTRONIC DEVICE, AND METHOD FOR MANUFACTURING SEMICONDUCTOR DEVICE

(71) Applicant: Kioxia Corporation, Tokyo (JP)

(72) Inventors: Kodai Eguchi, Kawasaki Kanagawa (JP); Ichiro Ide, Fujisawa Kanagawa (JP)

(73) Assignee: Kioxia Corporation, Tokyo (JP)

(21) Appl. No.: 17/894,756

(22) Filed: Aug. 24, 2022

(30) Foreign Application Priority Data
Mar. 4, 2022 (JP) 2022-033335

(51) Int. Cl. H05K 1/11; H01L 23/50; H05K 1/18; H05K 3/34

(52) U.S. Cl. CPC H05K 1/111; H01L 23/50; H05K 1/181; H05K 3/3436; H05K 3/3478; H05K 3/3485; H05K 2201/09381; H05K 2201/094; H05K 2201/10734

(57) ABSTRACT

A semiconductor device includes a substrate including a signal pad and a non-signal pad, a semiconductor housing portion including a signal pin and a first non-signal pin, and first bonding members configured to bond the signal pad and the signal pin and to bond the first non-signal pad and the first non-signal pin. The first non-signal pad and the first non-signal pin each have an L shape in a plan view.

### CROSS-REFERENCE TO RELATED APPLICATION(S)

This application is based upon and claims the benefit of priority from Japanese Patent Application No. 2022-033335, filed Mar. 4, 2022, the entire contents of which are incorporated herein by reference.

### FIELD

Embodiments described herein relate generally to a semiconductor device, an electronic device, and a method for manufacturing the semiconductor device.

### BACKGROUND

A semiconductor package, such as a ball grid array (BGA), generally includes solder balls on terminal pads of the BGA. Due to a difference between expansion or contraction that is caused by a temperature change on the semiconductor package and a substrate on which the semiconductor package is mounted, stress may be applied to the solder balls, and the solder balls of the terminal pads disposed at four corners of the semiconductor package may be broken or peeled off.

### DESCRIPTION OF THE DRAWINGS

FIG. 1 is a plan view of a semiconductor device according to a first embodiment.

FIG. 2 is a cross-sectional view taken along a line A-A in FIG. 1.

FIG. 3A is a top view of a substrate before bonding with a semiconductor housing portion according to the first embodiment.

FIG. 3B is a bottom view of the semiconductor housing portion before bonding with the substrate according to the first embodiment.

FIG. 3C is a cross-sectional view taken along a line A-A in FIGS. 3A and 3B.

FIG. 4A is a cross-sectional view showing a process for manufacturing the semiconductor device according to the first embodiment.

FIG. 4B is a cross-sectional view showing a process subsequent to FIG. 4A.

FIG. 4C is a cross-sectional view showing a process subsequent to FIG. 4B.

FIG. 4D is a cross-sectional view showing a process subsequent to FIG. 4C.

FIG. 5 is a cross-sectional view of a semiconductor device according to a second embodiment.

FIG. 6 is a cross-sectional view showing a process for manufacturing the semiconductor device according to the second embodiment.

FIG. 7 is a plan view of a semiconductor device according to a first modification of the second embodiment.

FIG. 8 is a cross-sectional view taken along a line B-B in FIG. 7.

FIG. 9 is a top view of a substrate before bonding with a semiconductor housing portion according to the first modification of the second embodiment.

FIG. 10A is a cross-sectional view showing a process for manufacturing the semiconductor device according to the first modification of the second embodiment.

FIG. 10B is a cross-sectional view showing a process subsequent to FIG. 10A.

FIG. 11 is a plan view of a semiconductor device according to a second modification of the second embodiment.

FIG. 12 is a cross-sectional view taken along a line C-C in FIG. 11.

FIG. 13 is a cross-sectional view showing a process for manufacturing the semiconductor device according to the second modification of the second embodiment.

FIG. 14 is a cross-sectional view of a semiconductor device according to a third embodiment.

FIG. 15 is a cross-sectional view showing a process for manufacturing the semiconductor device according to the third embodiment.

FIG. 16 is a plan view of a semiconductor device according to a first modification of the third embodiment.

FIG. 17 is a cross-sectional view taken along a line D-D in FIG. 16.

FIG. 18A is a cross-sectional view showing a process for manufacturing the semiconductor device according to the first modification of the third embodiment.

FIG. 18B is a cross-sectional view showing a process subsequent to FIG. 18A.

FIG. 19 is a plan view of a semiconductor device according to a second modification of the third embodiment.

FIG. 20 is a cross-sectional view taken along a line E-E in FIG. 19.

FIG. 21A is a cross-sectional view showing a process for manufacturing the semiconductor device according to the second modification of the third embodiment.

FIG. 21B is a cross-sectional view showing a process subsequent to FIG. 21A.

FIG. 22 is a plan view of a semiconductor device according to a fourth embodiment.

FIG. 23 is a cross-sectional view taken along a line F-F in FIG. 22.

FIG. 24A is a top view of a substrate before bonding with a semiconductor housing portion according to the fourth embodiment.

FIG. 24B is a bottom view of the semiconductor housing portion before bonding to the substrate according to the fourth embodiment.

FIG. 24C is a cross-sectional view taken along a line F-F in FIGS. 24A and 24B.

FIG. 25A is a cross-sectional view showing a process for manufacturing the semiconductor device according to the fourth embodiment.

FIG. 25B is a cross-sectional view showing a process subsequent to FIG. 25A.

FIG. 25C is a cross-sectional view showing a process subsequent to FIG. 25B.

FIG. 25D is a cross-sectional view showing a process subsequent to FIG. 25C.

FIG. 26A is a top view of an example of an electronic device that includes the semiconductor device according to at least one embodiment.

FIG. 26B is a bottom view of the example of the electronic device that includes the semiconductor device according to at least one embodiment.

FIG. 27 is a functional block diagram of the electronic device that includes the semiconductor device according to at least one embodiment.

FIG. 28 is a diagram showing an example of the electronic device that includes the semiconductor device according to at least one embodiment.

FIG. 29 is a diagram showing another example of the electronic device that includes the semiconductor device according to at least one embodiment.

FIG. 30 is a diagram showing still another example of the electronic device that includes the semiconductor device according to at least one embodiment.

### DETAILED DESCRIPTION

At least one embodiment provides a semiconductor device capable of improving resistance to stress of a bonding member.

In general, according to at least one embodiment, a semiconductor device includes: a substrate including a signal pad and a first non-signal pad; a semiconductor housing portion including a signal pin and a first non-signal pin; and first bonding members configured to bond the signal pad and the signal pin and to bond the first non-signal pad and the first non-signal pin. The first non-signal pad and the first non-signal pin each have an L shape in a plan view.

Next, embodiments will be described with reference to the drawings. In the description of the drawings described below, same or similar portions are denoted by same or similar reference numerals. The drawings are schematic.

The embodiments described below illustrate devices and methods for embodying technical ideas, and do not specify a material, a shape, a structure, an arrangement, and the like of each component. Various modifications may be made to the embodiments within the scope of the claims.

### First Embodiment

### Configuration of Semiconductor Device

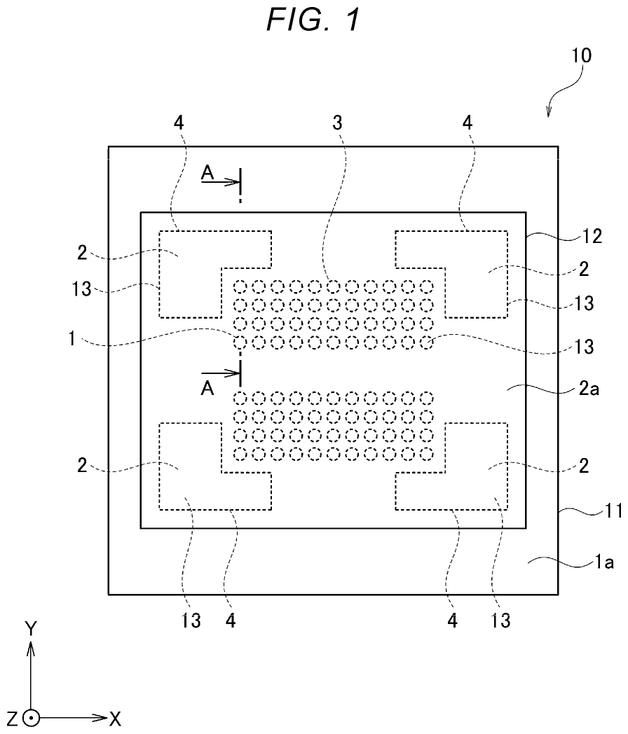

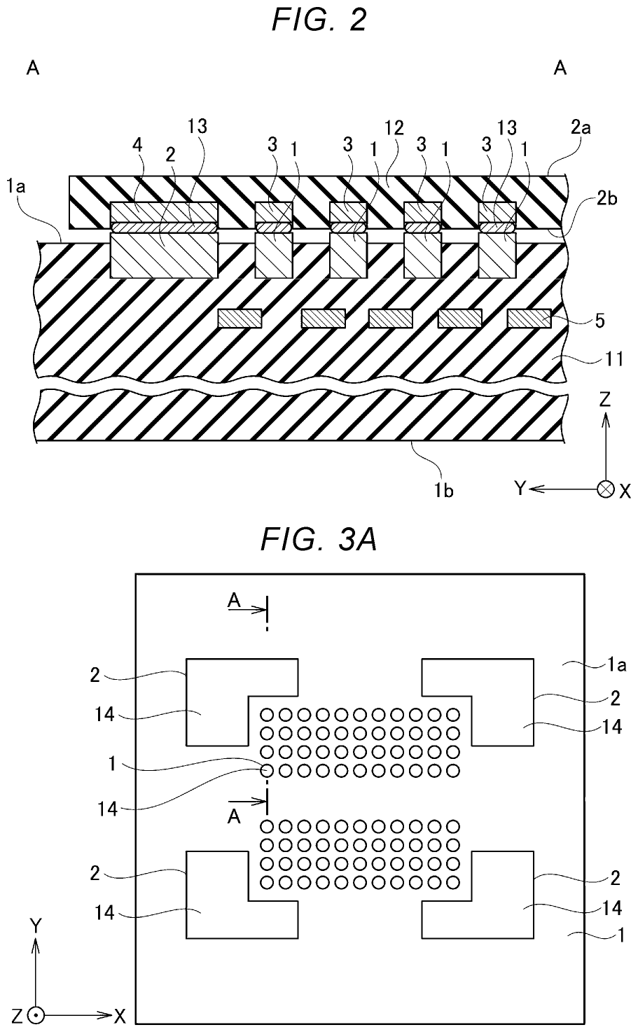

A semiconductor device 10 according to a first embodiment will be described. FIG. 1 is a plan view of the semiconductor device 10 according to the first embodiment. FIG. 2 is a cross-sectional view of the semiconductor device 10 according to the first embodiment taken along a line A-A shown in FIG. 1. In the following description, an XYZ coordinate system that is an example of an orthogonal coordinate system is used. That is, a plane parallel to a front surface of a substrate 11 constituting the semiconductor device 10 is set as an XY plane, and a direction orthogonal to the XY plane is set as a Z axis. In addition, an X axis and a Y axis are assumed to be two directions orthogonal to each other in the XY plane. Hereafter, for convenience of the description, the description will be made using an upper-lower relation in which a positive direction side (e.g., a side of a first main surface 1a of the substrate 11) of the Z axis is set as an upper side and a negative direction side (e.g., a side of a second main surface 1b of the substrate 11) of the Z axis is set as a lower side, but this upper-lower relation does not represent a universal upper-lower relation. In the following description, an upper portion is a portion located at a positive direction side of the Z axis of the substrate 11 or the semiconductor housing portion 12, and a lower portion is a portion located at a negative direction size of the Z axis of the substrate 11 or the semiconductor housing portion 12. That is, an upper side of the substrate 11 or the semiconductor housing portion 12 is also referred to as the upper portion, and a lower side of the substrate 11 or the semiconductor housing portion 12 is also referred to as the lower portion.

As shown in FIGS. 1 and 2, the semiconductor device 10 includes the substrate 11, the semiconductor housing portion 12, and first bonding members 13.

The semiconductor housing portion 12 is, for example, a semiconductor package. The semiconductor housing portion 12 houses a semiconductor chip. As shown in FIG. 2, the semiconductor housing portion 12 has a third main surface 2a and a fourth main surface 2b opposite to the third main surface 2a. The fourth main surface 2b faces the first main surface 1a of the substrate 11. The semiconductor housing portion 12 includes signal pins 3 and a first non-signal pin 4 on the fourth main surface 2b. The signal pins 3 are signal terminals. The signal terminals are, for example, terminals through which a signal communicated between an outside of the semiconductor housing portion 12 and the semiconductor chip housed in the semiconductor housing portion 12 passes. The first non-signal pin 4 is a non-signal terminal. The non-signal terminal is, for example, a terminal to which a ground potential or a power supply voltage supplied from the outside of the semiconductor housing portion 12 is connected. The semiconductor housing portion 12 may include at least one first non-signal pin 4.

The substrate 11 includes a multilayer wiring substrate. The substrate 11 is, for example, a print substrate. As shown in FIG. 2, the substrate 11 has the first main surface 1a and the second main surface 1b opposite to the first main surface 1a. The substrate 11 includes signal pads 1 and a first non-signal pad 2 on the first main surface 1a. The substrate 11 may have wirings 5 therein. The signal pads 1 are signal terminals. The first non-signal pad 2 is a non-signal terminal. The substrate 11 may include at least one first non-signal pad 2.

The signal pads 1 of the substrate 11 are electrically connected to the signal pins 3 of the semiconductor housing portion 12 via the first bonding members 13. The first non-signal pad 2 of the substrate 11 may be electrically connected to the first non-signal pin 4 of the semiconductor housing portion 12 via the first bonding member 13.

As shown in FIG. 1, the first non-signal pads 2 and the first non-signal pins 4 are located at four corners of an outer periphery of the semiconductor housing portion 12 in the plan view. Here, the four corners refer to four corners of the semiconductor housing portion 12. As shown in FIG. 1, the first non-signal pads 2 and the first non-signal pins 4 have an L shape in the plan view. Further, as shown in FIG. 1, an area of each of the first non-signal pads 2 and the first non-signal pins 4 is larger than an area of each of the signal pads 1 and the signal pins 3 in the plan view.

As shown in FIG. 1, the signal pads 1 and the signal pins 3 are located inside the semiconductor housing portion 12 with respect to the first non-signal pads 2 and the first non-signal pins 4 in the plan view. As shown in FIG. 1, the signal pads 1 and the signal pins 3 have a circular shape in the plan view. The signal pads 1 and the signal pins 3 may be a square shape or a rectangular shape in the plan view.

A semiconductor element may be provided in the semiconductor housing portion 12. An example of the semiconductor element is a nonvolatile memory such as a NAND flash memory chip. Another example of the semiconductor element is a volatile memory such as a dynamic random access memory (DRAM), a calculation element such as a microprocessor, or a signal processing element.

As shown in FIGS. 1 and 2, the first bonding members 13 bond the signal pads 1 and the signal pins 3, and bond the first non-signal pads 2 and the first non-signal pins 4. The first bonding members 13 are formed of, for example, a metal that bonds metals to each other. Specifically, the first bonding members 13 are solder balls or solder pastes.

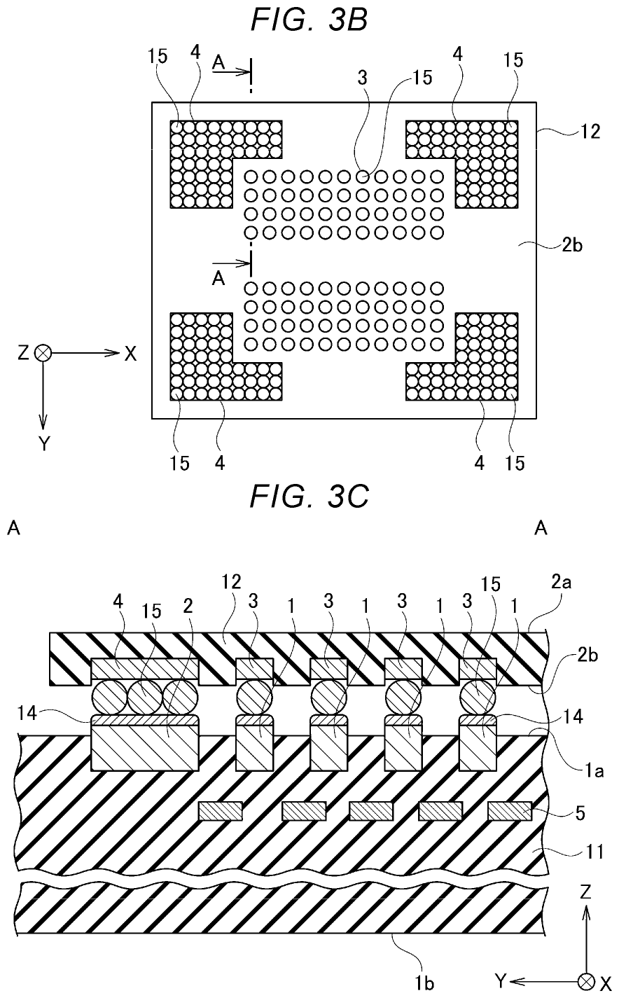

Next, a state before bonding the semiconductor housing portion 12 to the substrate 11 according to the first embodiment will be described. FIG. 3A is a top view of the substrate 11 before bonding with the semiconductor housing portion 12. FIG. 3B is a bottom view of the semiconductor housing portion 12 before bonding with the substrate 11. FIG. 3C is a cross-sectional view taken along a line A-A in FIGS. 3A and 3B.

As shown in FIGS. 3A and 3C, metal pastes 14 are disposed on the signal pads 1 and the first non-signal pads 2. The metal pastes 14 are electrically connected to the signal pads 1. The metal pastes 14 may be electrically connected to the first non-signal pads 2. Examples of the metal pastes 14 include solder pastes. In the following description, the metal pastes 14 are also referred to as solder pastes 14.

As shown in FIGS. 3B and 3C, metal balls 15 are disposed under the signal pins 3 and the first non-signal pins 4. The metal balls 15 are electrically connected to the signal pins 3. The metal balls 15 may be electrically connected to the first non-signal pins 4. Examples of the metal balls 15 include solder balls. In the following description, the metal balls 15 are also referred to as solder balls 15.

The solder pastes 14 and the solder balls 15 are heated to form the first bonding members 13 that bond the signal pads 1 and the signal pins 3, and bond the first non-signal pads 2 and the first non-signal pins 4.

### Method for Manufacturing Semiconductor Device

Next, a method for manufacturing the semiconductor device 10 according to the first embodiment will be described.

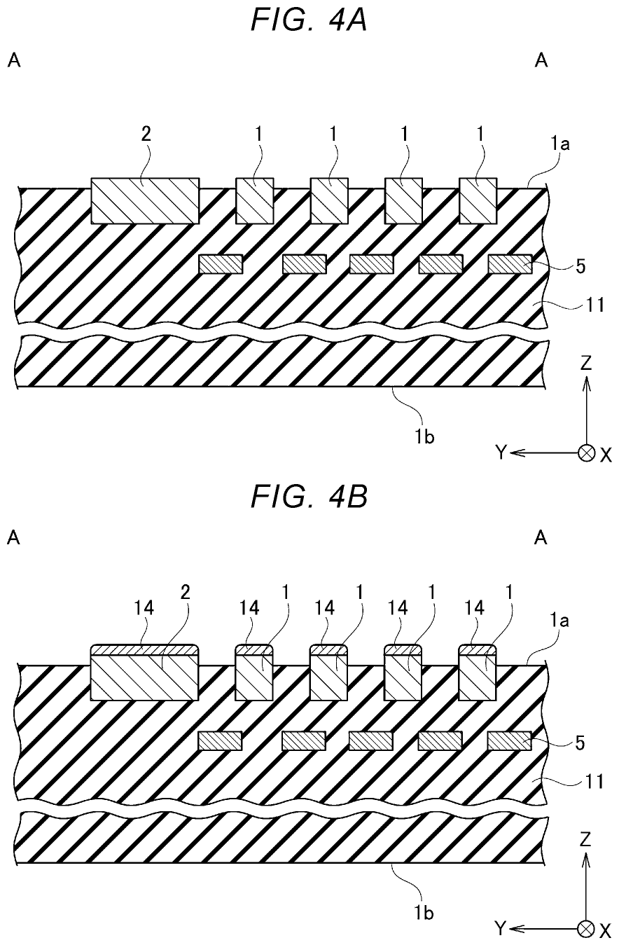

FIGS. 4A to 4D are views showing an example of the method for manufacturing the semiconductor device 10 according to the first embodiment.

First, as shown in FIG. 4A, the signal pads 1 and the first non-signal pad 2 are formed on the first main surface 1a of the substrate 11. Specifically, for example, a copper foil is bonded onto the first main surface 1a of the substrate 11, and the substrate 11 is patterned using a resist or the like as a mask member. The patterned mask member is wetly etched. A method for forming the signal pads 1 and the first non-signal pad 2 is not limited to the wet etching. Other methods, for example, a plating method may be used.

Next, as shown in FIG. 4B, the solder pastes 14 are applied onto the signal pads 1 and the first non-signal pad 2. Specifically, for example, the solder pastes 14 are applied using a metal mask.

Next, as shown in FIG. 4C, the semiconductor housing portion 12 to be bonded to the substrate 11 is prepared.

Next, as shown in FIG. 4D, the solder balls 15 each having a first size are formed under the signal pins 3 of the semiconductor housing portion 12. A plurality of solder balls 15 each having the first size are formed under the first non-signal pin 4. Specifically, for example, the solder balls 15 are disposed under the signal pins 3 and the first non-signal pin 4 by using a mask having holes into which the solder balls 15 fall. As a method for forming the solder balls 15 under the signal pins 3 and the first non-signal pin 4, other methods may be used. The plurality of solder balls 15 may be disposed under the first non-signal pin 4. In this case, the first size of each of the plurality of solder balls 15 disposed under the first non-signal pin 4 may be substantially the same as the first size of each of the solder balls 15 disposed under the signal pins 3.

Finally, the solder balls 15 are connected onto the solder pastes 14 to form the first bonding members 13. Specifically, for example, the solder pastes 14 are physically connected to the solder balls 15. Accordingly, as shown in FIG. 3C, the solder pastes 14 and the solder balls 15 are disposed between the signal pads 1 and the signal pins 3, and between the first non-signal pad 2 and the first non-signal pin 4. Next, the solder pastes 14 and the solder balls 15 are heated to be melted. Accordingly, as shown in FIG. 2, the solder pastes 14 and the solder balls 15 form the first bonding members 13.

According to the above manufacturing method, the semiconductor device 10 according to the first embodiment is manufactured.

According to the semiconductor device 10 in the first embodiment, resistance to stress of the bonding members is improved by increasing bonding areas of the first non-signal pads 2 and the first non-signal pins 4.

According to the semiconductor device 10 of the first embodiment, the resistance to the stress of the bonding members is improved between the first non-signal pad 2 and first non-signal pin 4. Accordingly, a protective resin of the solder balls 15, such as an under fill or a corner fill, is not required, and a cost can be reduced. Recovery work (repair) when a defect occurs in the semiconductor device 10 is facilitated.

### Second Embodiment

### Configuration of Semiconductor Device

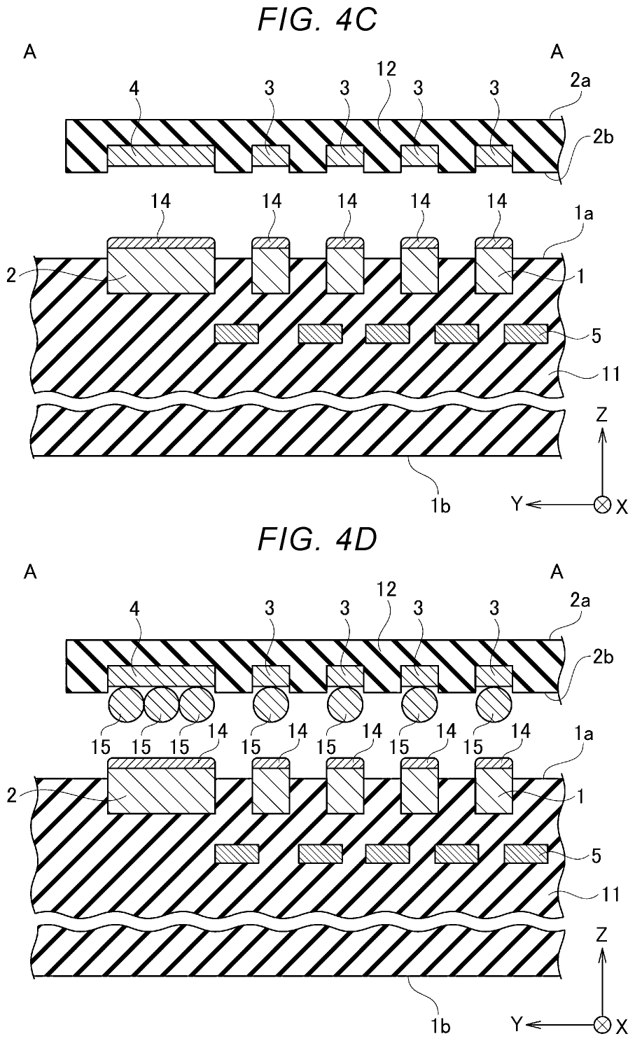

FIG. 5 is a cross-sectional view of a semiconductor device 20 according to a second embodiment.

As shown in FIG. 5, the semiconductor device 20 includes a second non-signal pad 2A instead of the first non-signal pad 2 of the semiconductor device 10 according to the first embodiment. The second non-signal pad 2A is another example of a first non-signal pad. In addition, the semiconductor device 20 includes a second bonding member 13A in addition to the first bonding members 13. The second bonding member 13A is another example of a first bonding member. Since other configurations are the same as those of the semiconductor device 10 according to the first embodiment, a description thereof is omitted.

Here, as shown in FIG. 5, a thickness tPAD1 of the signal pads 1 is a height of the signal pads 1 in the Z direction with reference to the first main surface 1a of the substrate 11. A thickness tPAD2 of the second non-signal pad 2A is a height of the second non-signal pad 2A in the Z direction with reference to the first main surface 1a of the substrate 11. The thickness of the second non-signal pad 2A is larger than the thickness of the signal pads 1 in a cross-sectional view (tPAD2>tPAD1).

The second bonding member 13A bonds the second non-signal pad 2A and the first non-signal pin 4. As shown in FIG. 5, an amount of solder contained in the second bonding member 13A is smaller than that of the first bonding member 13 that bonds the signal pad 1 and the signal pin 3. That is, in the plan view, the solder amount of the second bonding member 13A per unit area of the second non-signal pad 2A and the first non-signal pin 4 is smaller than the solder amount of the first bonding members 13 per unit area of the signal pads 1 and the signal pins 3. Therefore, the second bonding member 13A is thinner than the first bonding members 13.

### Method for Manufacturing Semiconductor Device

Next, a method for manufacturing the semiconductor device 20 according to the second embodiment will be described.

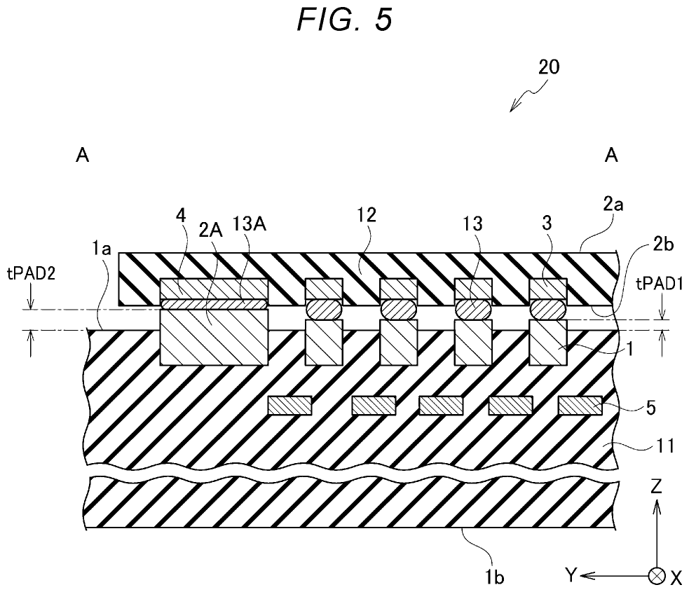

FIG. 6 is a view showing an example of the method for manufacturing the semiconductor device 20 according to the second embodiment.

First, as shown in FIG. 6, the signal pads 1 and the second non-signal pad 2A are formed on the first main surface 1a of the substrate 11. Specifically, for example, a copper foil is bonded onto the first main surface 1a of the substrate 11, and the substrate 11 is patterned using a resist or the like as a mask member. The patterned mask member is wetly etched. It is possible to cause the pad thickness tPAD1 of the signal pads 1 to be different from the thickness tPAD2 of the second non-signal pad 2A by employing different wet etching time periods for the signal pads 1 and the second non-signal pad 2A. The method for forming the signal pads 1 and the second non-signal pad 2A is not limited to the wet etching. Other methods, for example, a plating method may be used. Since subsequent processes are the same as those of the method for manufacturing the semiconductor device 10 according to the first embodiment, a description thereof is omitted.

According to the above manufacturing method, the semiconductor device 20 according to the second embodiment is manufactured.

According to the semiconductor device 20 of the second embodiment, the thickness tPAD2 of the second non-signal pad 2A is larger than the thickness tPAD1 of the signal pad 1. Accordingly, even if the solder amount of the second bonding member 13A is smaller than the solder amount of the first bonding member 13, the second non-signal pad 2A and the first non-signal pin 4 can be bonded.

### First Modification of Second Embodiment

### Configuration of Semiconductor Device

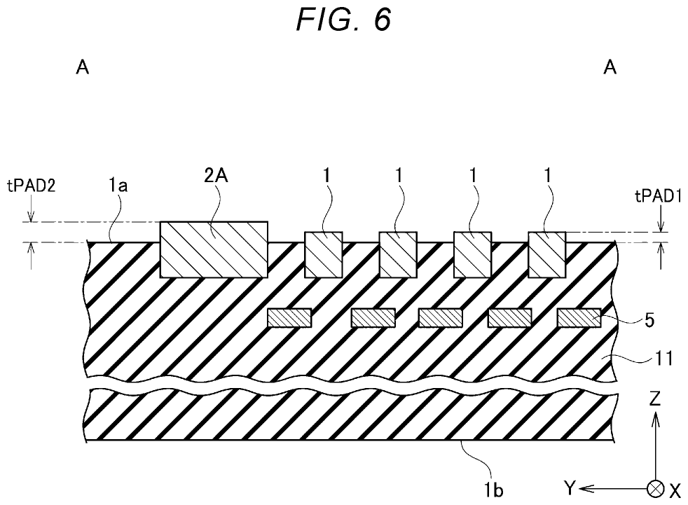

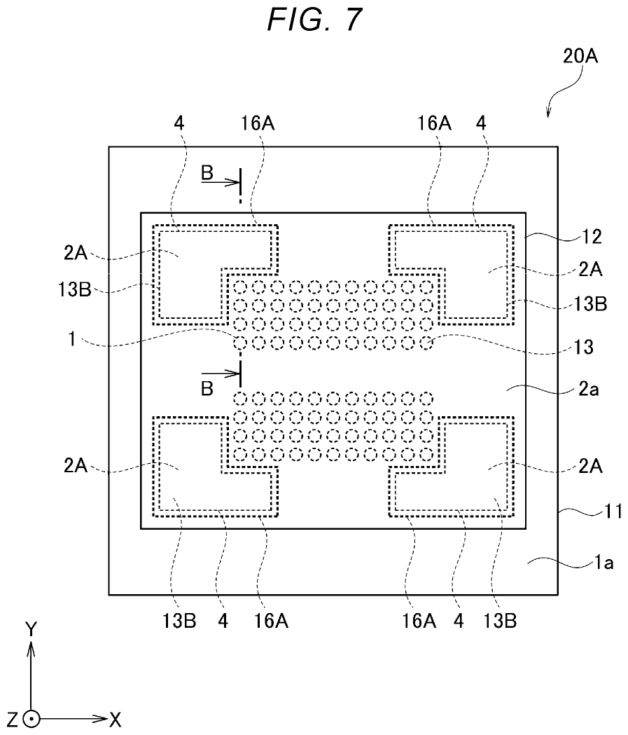

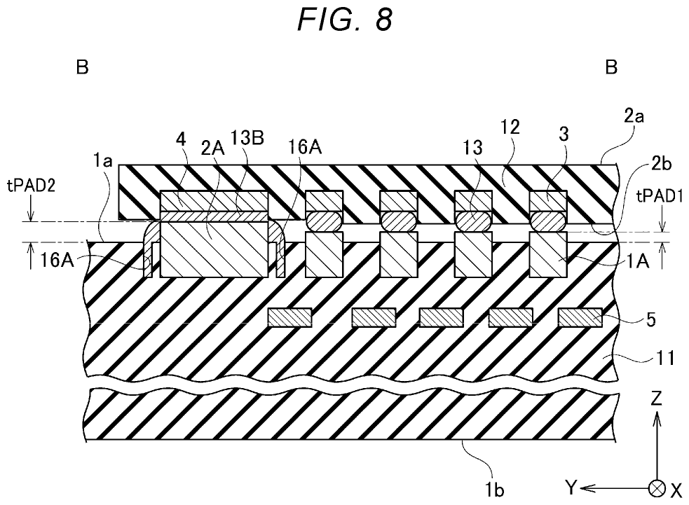

FIG. 7 is a plan view of a semiconductor device 20A according to a first modification of the second embodiment. FIG. 8 is a cross-sectional view of the semiconductor device 20A according to the first modification of the second embodiment taken along a line B-B shown in FIG. 7. FIG. 9 is a top view of the substrate 11 before bonding with the semiconductor housing portion 12.

As shown in FIG. 7, the semiconductor device 20A has grooves 16A. In addition, the semiconductor device 20A includes third bonding members 13B instead of the first bonding members 13 of the semiconductor device 20 according to the second embodiment. The third bonding members 13B are still another example of the first bonding member. Since other configurations are the same as those of the semiconductor device 20 according to the second embodiment, a description thereof is omitted.

As shown in FIGS. 7 to 9, the substrate 11 has the grooves 16A. The groove 16A surrounds an outer periphery of the second non-signal pad 2A. At least a part of the groove 16A is formed between the second non-signal pad 2A and the signal pads 1 in the plan view.

As shown in FIG. 8, the third bonding member 13B bonds the second non-signal pad 2A and the first non-signal pin 4. The groove 16A may be filled with a part of the third bonding member 13B. That is, when the second non-signal pad 2A is bonded with the first non-signal pin 4 by the third bonding member 13B, the groove 16A can be filled with an excessive portion of the third bonding member 13B. Accordingly, a short circuit between the second non-signal pad 2A and the signal pads 1 can be prevented.

### Method for Manufacturing Semiconductor Device

Next, a method for manufacturing the semiconductor device 20A according to the first modification of the second embodiment will be described. A difference from the method for manufacturing the semiconductor device 20 according to the second embodiment will be described below.

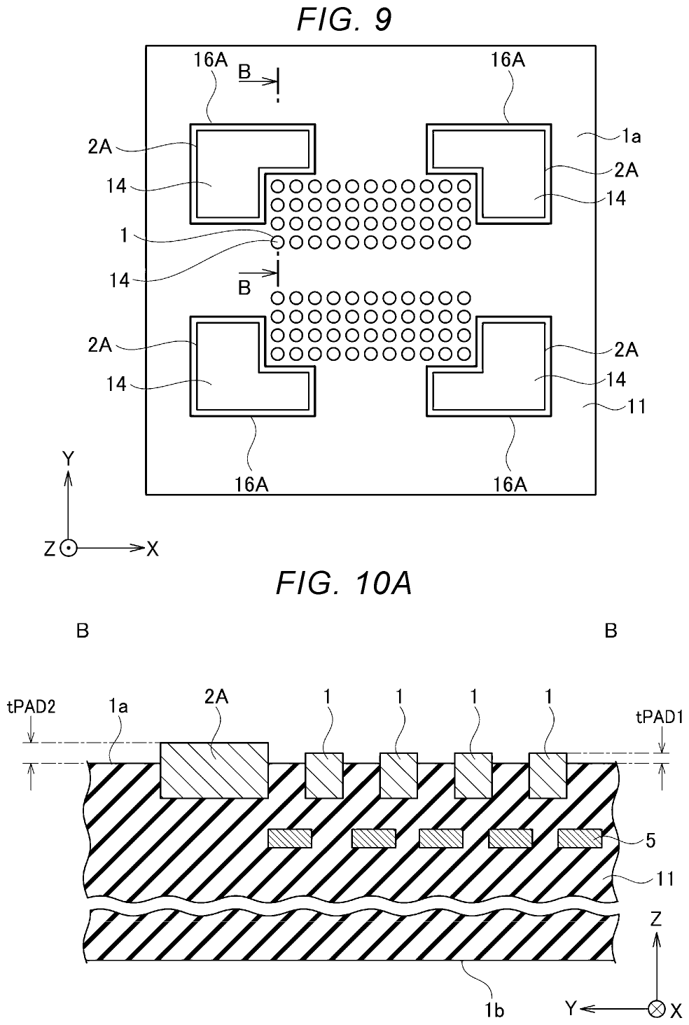

FIGS. 10A and 10B are views showing an example of the method for manufacturing the semiconductor device 20A according to the first modification of the second embodiment.

First, as shown in FIG. 10A, the signal pads 1 and the second non-signal pad 2A are formed on the first main surface 1a of the substrate 11. Specifically, for example, a copper foil is bonded onto the first main surface 1a of the substrate 11, and the substrate 11 is patterned using a resist or the like as a mask member. The patterned mask member is wet etched. It is possible to cause the thickness tPAD1 of the signal pad 1 to be different from the thickness tPAD2 of the second non-signal pad 2A by employing different wet etching time periods for the signal pads 1 and the second non-signal pad 2A. The method for forming the signal pads 1 and the second non-signal pad 2A is not limited to the wet etching.

Next, as shown in FIG. 10B, the groove 16A is formed on the first main surface 1a of the substrate 11 in a manner of surrounding an outer periphery of the second non-signal pad 2A. Specifically, the substrate 11 is masked with a resist and is wet etched. A method for forming the groove 16A is not limited to the wet etching. Other methods of dry etching and cutting with a drill may be used. Since subsequent processes are the same as those of the method for manufacturing the semiconductor device 20 according to the second embodiment, a description thereof is omitted.

According to the above manufacturing method, the semiconductor device 20A according to the first modification of the second embodiment is manufactured.

The semiconductor device 20A according to the first modification of the second embodiment has the groove 16A surrounding the outer periphery of the second non-signal pad 2A. Accordingly, even if a solder amount of the third bonding member 13B is excessive, the groove 16A can be filled with a part of the third bonding member 13B, and a short circuit between the second non-signal pad 2A and the signal pads 1 can be prevented.

### Second Modification of Second Embodiment

### Configuration of Semiconductor Device

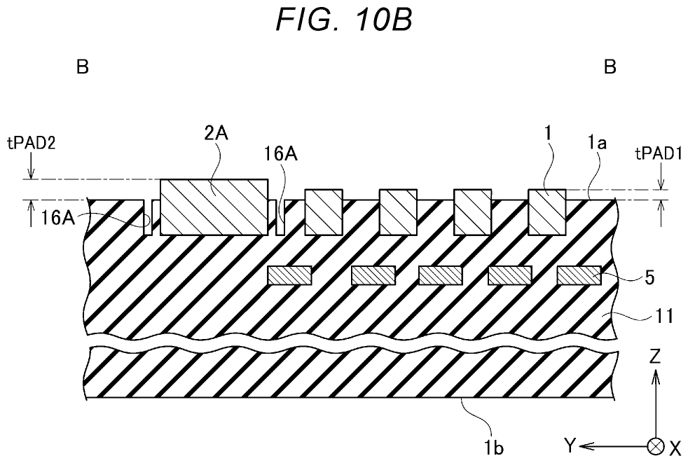

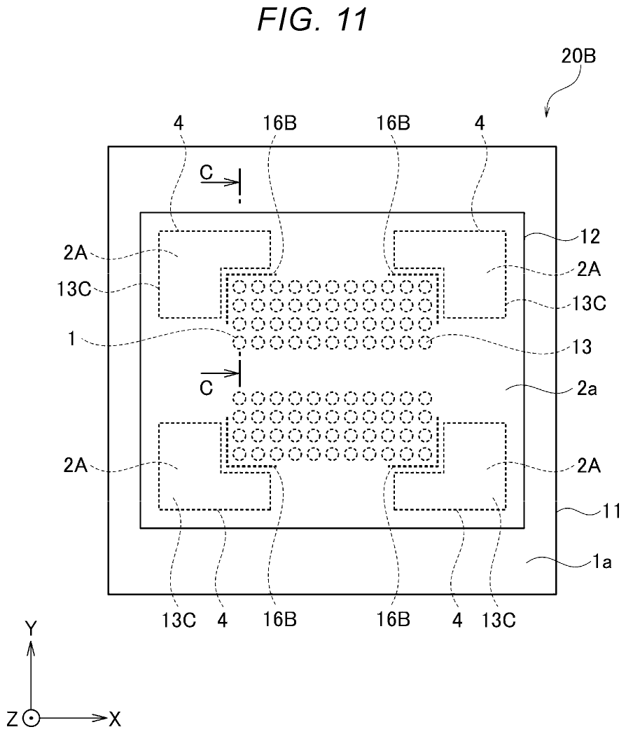

FIG. 11 is a plan view of a semiconductor device 20B according to a second modification of the second embodiment. FIG. 12 is a cross-sectional view of the semiconductor device 20B according to the second modification of the second embodiment taken along a line C-C shown in FIG. 11.

As shown in FIG. 11, the semiconductor device 20B has grooves 16B instead of the grooves 16A. The grooves 16B are another example of a groove. In addition, the semiconductor device 20B includes fourth bonding members 13C instead of the third bonding members 13B of the semiconductor device 20A according to the first modification of the second embodiment. The fourth bonding members 13C are still another example of the first bonding member. Since other configurations are the same as those of the semiconductor device 20A according to the first modification of the second embodiment, a description thereof is omitted.

As shown in FIG. 12, the fourth bonding member 13C bonds the second non-signal pad 2A and the first non-signal pin 4. The groove 16B may be filled with a part of the fourth bonding member 13C.

As shown in FIGS. 11 and 12, the groove 16B is separated from the second non-signal pad 2A and the signal pads 1. That is, when the second non-signal pad 2A is bonded with the first non-signal pin 4 by the fourth bonding member 13C, the groove 16B can be filled with an excessive portion of the fourth bonding member 13C. Accordingly, a short circuit between the second non-signal pad 2A and the signal pads 1 can be prevented.

### Method for Manufacturing Semiconductor Device

Next, a method for manufacturing the semiconductor device 20B according to the second modification of the second embodiment will be described.

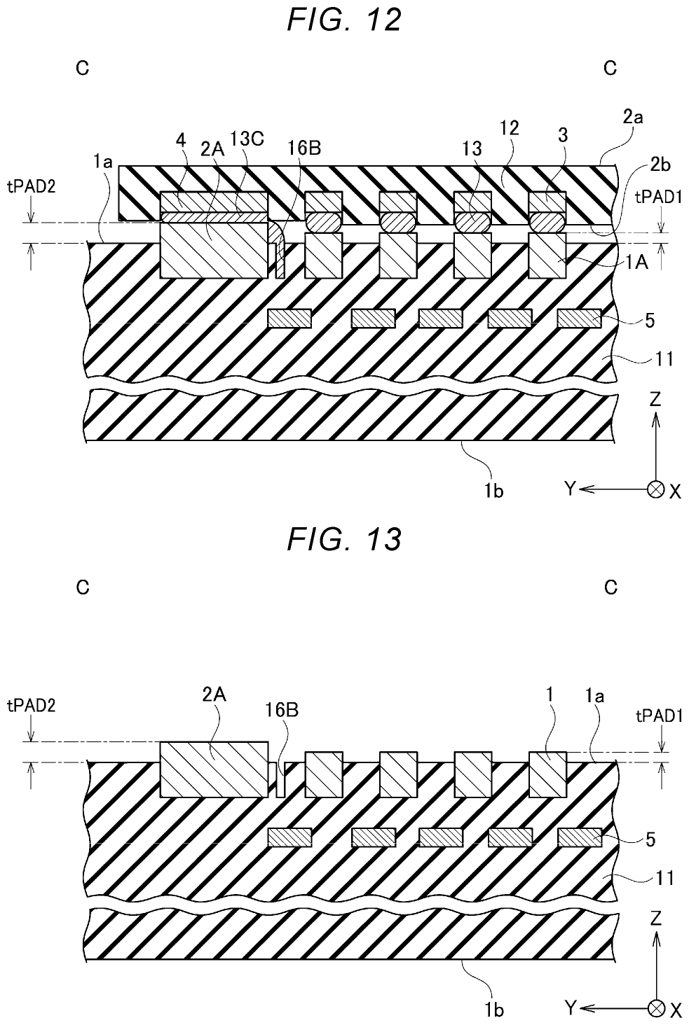

FIG. 13 is a view showing an example of the method for manufacturing the semiconductor device 20B according to the second modification of the second embodiment.

As shown in FIG. 13, the groove 16B is formed between the second non-signal pad 2A and the signal pad 1 in the manufacturing of the semiconductor device 20B. Since other processes are the same as those of the method for manufacturing the semiconductor device 20A according to the first modification of the second embodiment, a description thereof is omitted.

According to the above manufacturing method, the semiconductor device 20B according to the second modification of the second embodiment is manufactured.

The semiconductor device 20B according to the second modification of the second embodiment has the groove 16B formed between the second non-signal pad 2A and the signal pad 1. Accordingly, even if a solder amount of the fourth bonding member 13C is excessive, the groove 16B can be filled with a part of the fourth bonding member 13C, and a short circuit between the second non-signal pad 2A and the signal pads 1 can be prevented. The groove 16B is different from the groove 16A, and is not formed in a manner of surrounding an outer periphery of the second non-signal pad 2A. Therefore, the groove 16B can be formed at a lower cost than the groove 16A.

### Third Embodiment

### Configuration of Semiconductor Device

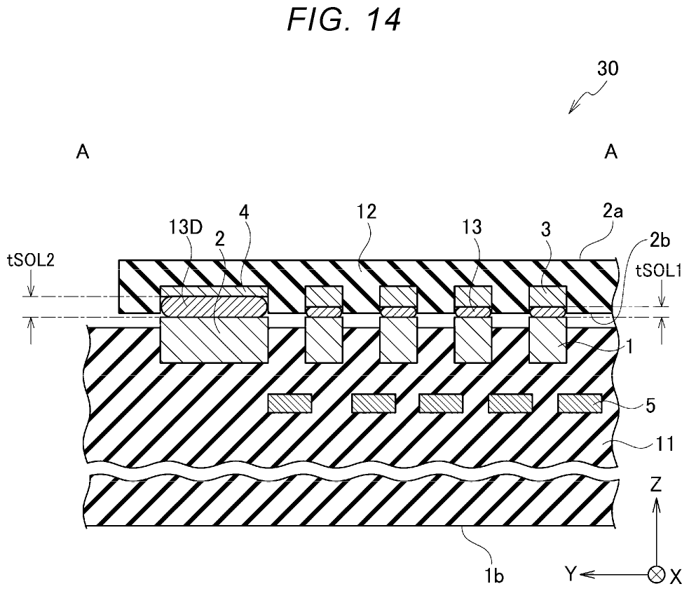

FIG. 14 is a cross-sectional view of a semiconductor device 30 according to a third embodiment.

As shown in FIG. 14, the semiconductor device 30 includes a fifth bonding member 13D in addition to the first bonding members 13 of the semiconductor device 10 according to the first embodiment. The fifth bonding member 13D is still another example of the first bonding member. Since other configurations are the same as those of the semiconductor device 10 according to the first embodiment, a description thereof is omitted.

As shown in FIG. 14, a thickness tSOL1 of the first bonding member 13 is a distance from the signal pads 1 to the signal pins 3. A thickness tSOL2 of the fifth bonding member 13D is a distance from the first non-signal pad 2 to the first non-signal pin 4. The thickness tSOL2 of the fifth bonding member 13D is larger than the thickness of the first bonding member 13 in the cross-sectional view (i.e., tSOL2>tSOL1). The thickness of the first non-signal pin 4 may be smaller than the thickness of the signal pin 3 in the cross-sectional view. Alternatively, the thickness of the first non-signal pad 2 may be smaller than the thickness of the signal pad 1 in the cross-sectional view.

The fifth bonding member 13D bonds the first non-signal pad 2 and the first non-signal pin 4. An amount of solder (a solder paste or a solder ball) per unit area contained in the fifth bonding member 13D in the plan view is larger than that of the first bonding member 13 that bonds the signal pad 1 and the signal pin 3. The fifth bonding member 13D containing the solder in an amount larger than that in the first bonding members 13 can fill a space between the first non-signal pad 2 and the first non-signal pin 4 without a gap, and can firmly bond the first non-signal pad 2 and the first non-signal pin 4.

Method for Manufacturing Semiconductor Device

Next, a method for manufacturing the semiconductor device 30 according to the third embodiment will be described.

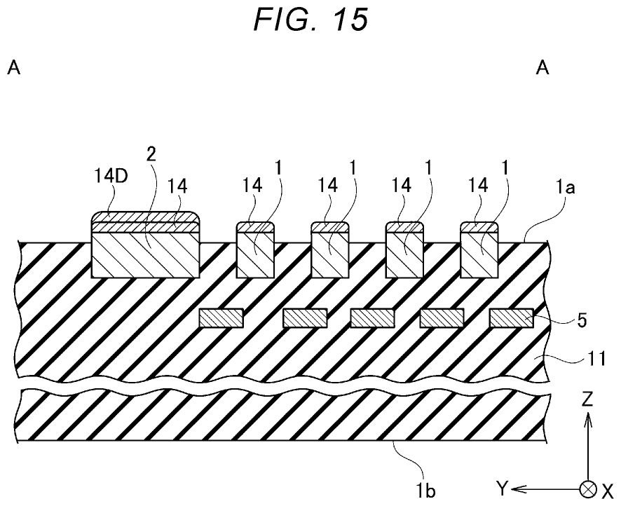

FIG. 15 is a view showing an example of the method for manufacturing the semiconductor device 30 according to the third embodiment.

As shown in FIG. 15, the solder pastes 14 are applied onto the signal pads 1 and the first non-signal pad 2. Specifically, for example, the solder pastes 14 are printed using a metal mask. Next, a solder paste 14D is applied onto the first non-signal pad 2 such that the solder paste 14D is laminated on the solder paste 14. The solder paste 14 and the solder paste 14D that are applied onto the first non-signal pad 2 are melted by being heated together with the solder balls 15 formed under the first non-signal pin 4, and form the fifth bonding member 13D. Since other processes are the same as those of the method for manufacturing the semiconductor device 10 according to the first embodiment, a description thereof is omitted.

According to the above manufacturing method, the semiconductor device 30 according to the third embodiment is manufactured.

According to the semiconductor device 30 of the third embodiment, the thickness tSOL2 of the fifth bonding member 13D is larger than the thickness tSOL1 of the first bonding member 13. Accordingly, even if a distance between the first non-signal pad 2 and the first non-signal pin 4 is larger than a distance between the signal pad 1 and the signal pin 3, the first non-signal pad 2 and the first non-signal pin 4 can be firmly bonded.

### First Modification of Third Embodiment

### Configuration of Semiconductor Device

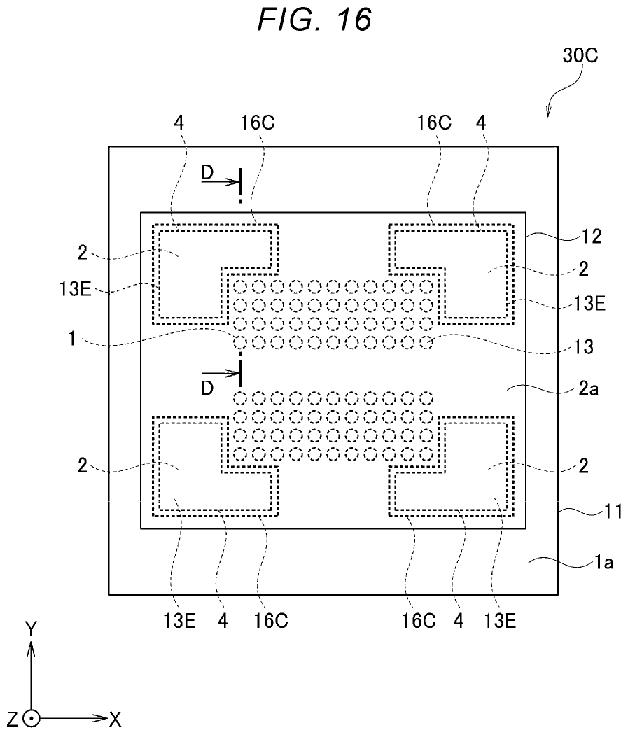

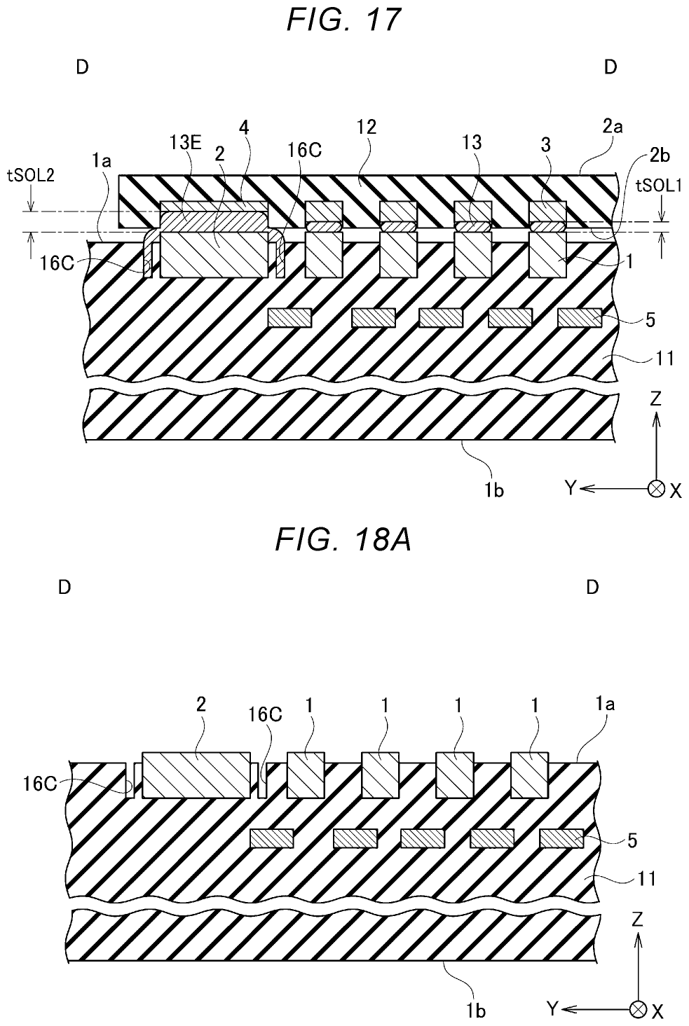

FIG. 16 is a plan view of a semiconductor device 30C according to a first modification of the third embodiment. FIG. 17 is a cross-sectional view of the semiconductor device 30C according to the first modification of the third embodiment taken along a line D-D shown in FIG. 16.

As shown in FIG. 16, the semiconductor device 30C has grooves 16C. The grooves 16C are still another example of the groove. In addition, the semiconductor device 30C includes sixth bonding members 13E instead of the fifth bonding members 13D of the semiconductor device 30 according to the third embodiment. The sixth bonding members 13E are still another example of the first bonding member. Since other configurations are the same as those of the semiconductor device 30 according to the third embodiment, a description thereof is omitted.

As shown in FIG. 17, the sixth bonding member 13E bonds the first non-signal pad 2 and the first non-signal pin 4. The groove 16C may be filled with a part of the sixth bonding member 13E.

As shown in FIGS. 16 and 17, the groove 16C surrounds an outer periphery of the first non-signal pad 2. At least a part of the groove 16C is formed between the first non-signal pad 2 and the signal pad 1 in the plan view. Accordingly, when the first non-signal pad 2 is bonded with the first non-signal pin 4 by the sixth bonding member 13E, the groove 16C can be filled with an excessive portion of the sixth bonding member 13E. Accordingly, a short circuit between the first non-signal pad 2 and the signal pads 1 can be prevented.

### Method for Manufacturing Semiconductor Device

Next, a method for manufacturing the semiconductor device 30C according to the first modification of the third embodiment will be described. A difference from the method for manufacturing the semiconductor device 30 according to the third embodiment will be described below.

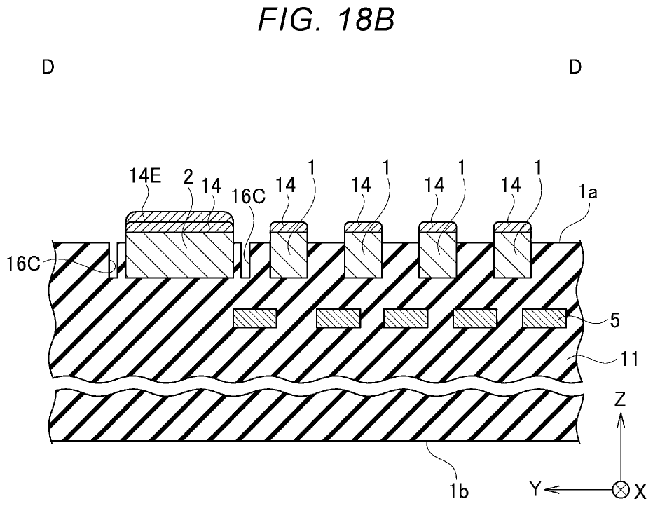

FIGS. 18A and 18B are views showing an example of the method for manufacturing the semiconductor device 30C according to the first modification of the third embodiment.

As shown in FIG. 18A, the groove 16C is formed on the first main surface 1a of the substrate 11 in a manner of surrounding an outer periphery of the first non-signal pad 2. Specifically, the substrate 11 is masked with a resist and is wet etched. A method for forming the groove 16C is not limited to the wet etching. Other methods of dry etching and cutting with a drill may be used.

Next, as shown in FIG. 18B, the solder pastes 14 are applied onto the signal pads 1 and the first non-signal pad 2. Specifically, for example, the solder pastes 14 are printed using a metal mask. Next, a solder paste 14E is printed onto the first non-signal pad 2 such that the solder paste 14E is laminated on the solder paste 14. Since other processes are the same as those of the method for manufacturing the semiconductor device 30 according to the third embodiment, a description thereof is omitted.

According to the above manufacturing method, the semiconductor device 30C according to the first modification of the third embodiment is manufactured.

The semiconductor device 30C according to the first modification of the third embodiment has the groove 16C surrounding an outer periphery of the first non-signal pad 2. Accordingly, even if a solder amount of the sixth bonding member 13E is excessive, the groove 16C can be filled with a part of the sixth bonding member 13E, and a short circuit between the first non-signal pad 2 and the signal pads 1 can be prevented.

### Second Modification of Third Embodiment

### Configuration of Semiconductor Device

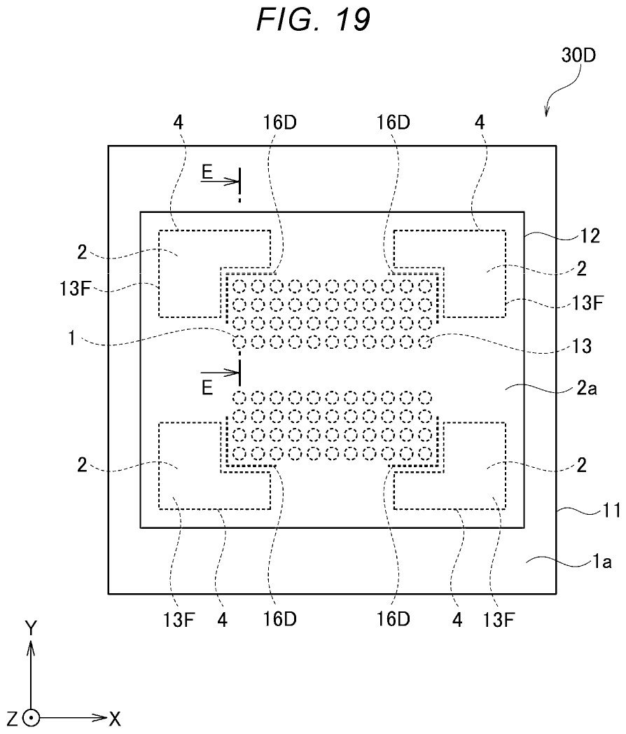

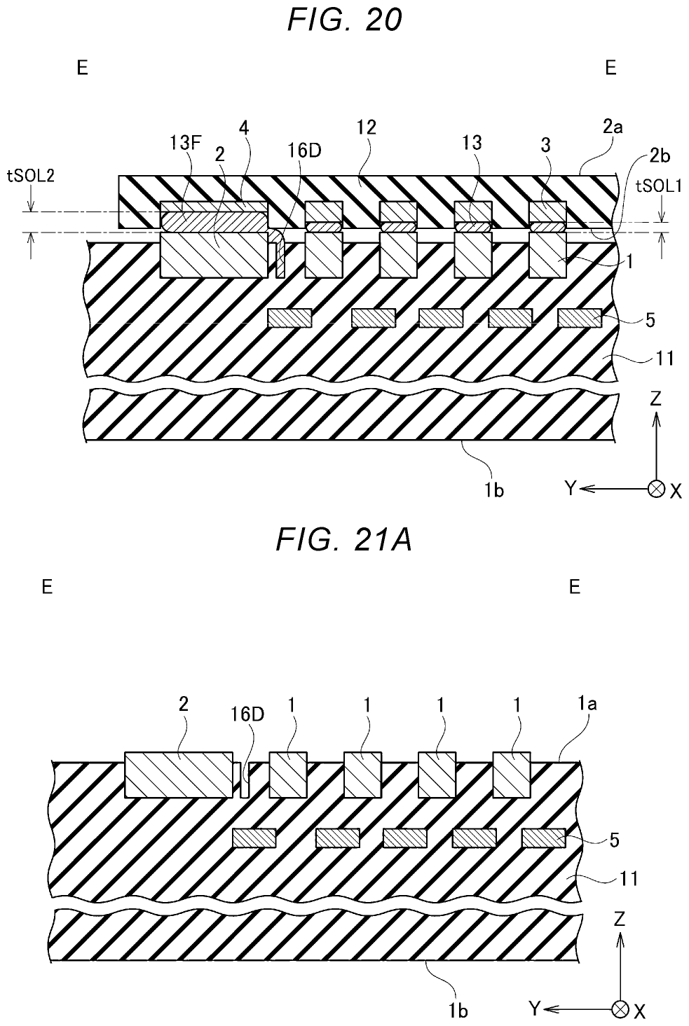

FIG. 19 is a plan view of a semiconductor device 30D according to a second modification of the third embodiment. FIG. 20 is a cross-sectional view of the semiconductor device 30D according to the second modification of the third embodiment taken along a line E-E shown in FIG. 19.

As shown in FIG. 19, the semiconductor device 30D has grooves 16D instead of the grooves 16C. The grooves 16D are still another example of the groove. In addition, the semiconductor device 30D includes seventh bonding members 13F instead of the sixth bonding members 13E of the semiconductor device 30C according to the first modification of the third embodiment. The seventh bonding members 13F are still another example of the first bonding member. Since other configurations are the same as those of the semiconductor device 30C according to the first modification of the third embodiment, a description thereof is omitted.

As shown in FIG. 20, the seventh bonding member 13F bonds the first non-signal pad 2 and the first non-signal pin 4. The groove 16D may be filled with a part of the seventh bonding member 13F.

As shown in FIGS. 19 and 20, the groove 16D is disposed between the first non-signal pad 2 and the signal pad 1 and separated therefrom. That is, when the first non-signal pad 2 is bonded with the first non-signal pin 4 by the seventh bonding member 13F, the groove 16D can be filled with an excessive portion of the seventh bonding member 13F. Accordingly, a short circuit between the first non-signal pad 2 and the signal pads 1 can be prevented.

### Method for Manufacturing Semiconductor Device

Next, a method for manufacturing the semiconductor device 30D according to the second modification of the third embodiment will be described. A difference from the method for manufacturing the semiconductor device 30C according to the first modification of the third embodiment will be described below.

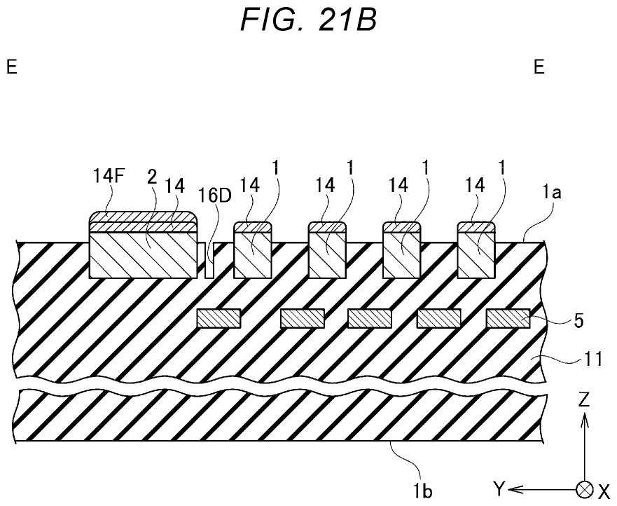

FIGS. 21A and 21B are views showing an example of the method for manufacturing the semiconductor device 30D according to the second modification of the third embodiment.

As shown in FIG. 21A, the groove 16D is formed between the first non-signal pad 2 and the signal pad 1 in the manufacturing of the semiconductor device 30D.

Next, as shown in FIG. 21B, the solder pastes 14 are applied onto the signal pads 1 and the first non-signal pad 2. Specifically, for example, the solder pastes 14 are printed using a metal mask. Next, a solder paste 14F is printed onto the first non-signal pad 2 such that the solder paste 14F is laminated on the solder paste 14. Since other processes are the same as those of the method for manufacturing the semiconductor device 30C according to the first modification of the third embodiment, a description thereof is omitted.

According to the above manufacturing method, the semiconductor device 30D according to the second modification of the third embodiment is manufactured.

The semiconductor device 30D according to the second modification of the third embodiment has the groove 16D formed between the first non-signal pad 2 and the signal pad 1. Accordingly, even if a solder amount of the seventh bonding member 13F is excessive, the groove 16D can be filled with a part of the seventh bonding member 13F, and a short circuit between the first non-signal pad 2 and the signal pads 1 can be prevented. The groove 16D is different from the groove 16C, and is not formed in a manner of surrounding an outer periphery of the first non-signal pad 2. Therefore, the groove 16D can be formed at a lower cost than the groove 16C.

### Fourth Embodiment

### Configuration of Semiconductor Device

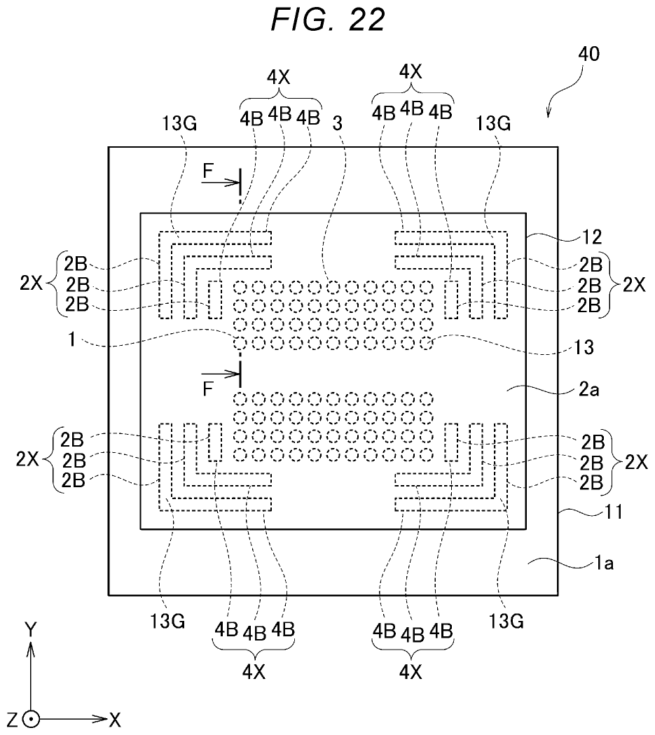

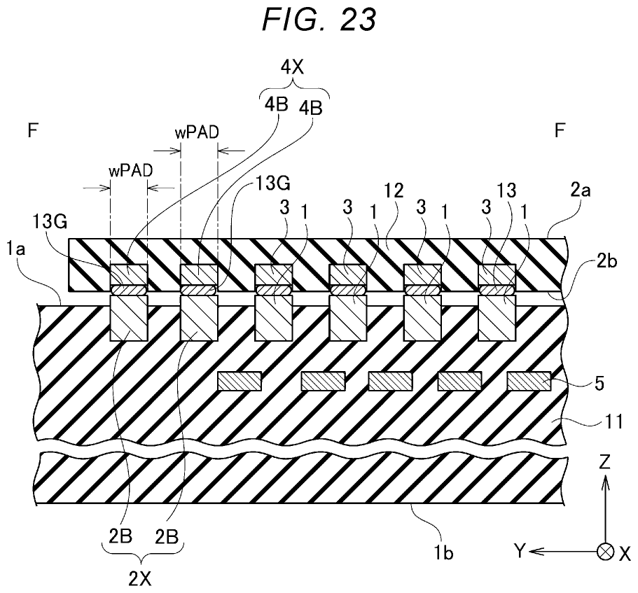

FIG. 22 is a plan view of a semiconductor device 40 according to a fourth embodiment. FIG. 23 is a cross-sectional view of the semiconductor device 40 according to the fourth embodiment taken along a line F-F shown in FIG. 22.

As shown in FIG. 22, the semiconductor device 40 includes, instead of the first non-signal pads 2 and the first non-signal pins 4 of the semiconductor device 10 according to the first embodiment, third non-signal pad groups 2X each including one or more third non-signal pads 2B and second non-signal pin groups 4X each including one or more second non-signal pins 4B. The third non-signal pads 2B are another example of the first non-signal pad. The second non-signal pins 4B are another example of the first non-signal pin. In addition, the semiconductor device 40 includes eighth bonding members 13G in addition to the first bonding members 13. The eighth bonding members 13G are still another example of the first bonding member. Since other configurations are the same as those of the semiconductor device 10 according to the first embodiment, a description thereof is omitted.

As shown in FIG. 22, the third non-signal pad groups 2X and the second non-signal pin groups 4X are located at four corners of an outer periphery of the semiconductor housing portion 12 in the plan view. As shown in FIG. 22, the third non-signal pads 2B and the second non-signal pins 4B each have an L shape in the plan view. The third non-signal pads 2B are separated from each other. The second non-signal pins 4B are separated from each other.

Here, as shown in FIG. 23, the third non-signal pads 2B and the second non-signal pins 4B each have a first line width wPAD. The first line width wPAD may be, for example, substantially the same as the diameter of a solder ball for bonding the third non-signal pad 2B with the second non-signal pin 4B. The first line width wPAD may be substantially the same as width of the signal pad 1 and the signal pin 3. By dividing the third non-signal pads 2B and the second non-signal pins 4B into the first line width wPAD, areas of the third non-signal pad group 2X and the second non-signal pin group 4X are reduced in the plan view. Accordingly, an amount of the eighth bonding members 13G per unit area of the third non-signal pad group 2X and the second non-signal pin group 4X increases. That is, amounts of a solder paste and a solder ball per unit area of the third non-signal pad group 2X and the second non-signal pin group 4X increase in the plan view.

As shown in FIGS. 22 and 23, the eighth bonding members 13G bond the third non-signal pads 2B and the second non-signal pins 4B. The eighth bonding members 13G are formed of, for example, a metal that bonds metals to each other. Specifically, the eighth bonding members 13G are solder balls, or solder pastes.

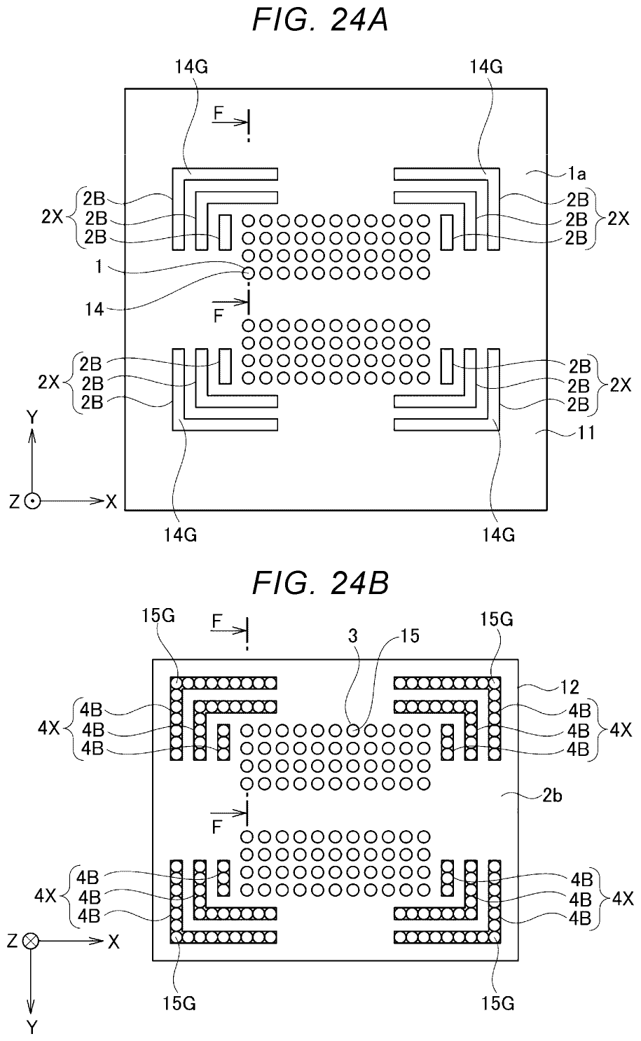

Next, a state before bonding the substrate 11 with the semiconductor housing portion 12 according to the fourth embodiment will be described. FIG. 24A is a top view of the substrate 11 before bonding with the semiconductor housing portion 12. FIG. 24B is a bottom view of the semiconductor housing portion 12 before bonding to the substrate 11. FIG. 24C is a cross-sectional view taken along a line F-F in FIGS. 24A and 24B.

As shown in FIGS. 24A and 24C, metal pastes 14G are disposed on the third non-signal pads 2B. The metal pastes 14G may be electrically connected to the third non-signal pads 2B. Examples of the metal pastes 14G include solder pastes. In the following description, the metal pastes 14G are also referred to as solder pastes 14G.

As shown in FIGS. 24B and 24C, metal balls 15G are disposed under the second non-signal pins 4B. The metal balls 15G may be electrically connected to the second non-signal pins 4B. Examples of the metal balls 15G include solder balls. In the following description, the metal balls 15G are also referred to as solder balls 15G.

The solder pastes 14G and the solder balls 15G are heated to form the eighth bonding members 13G that bond the third non-signal pads 2B and the second non-signal pins 4B.

Method for Manufacturing Semiconductor Device

Next, a method for manufacturing the semiconductor device 40 according to the fourth embodiment will be described.

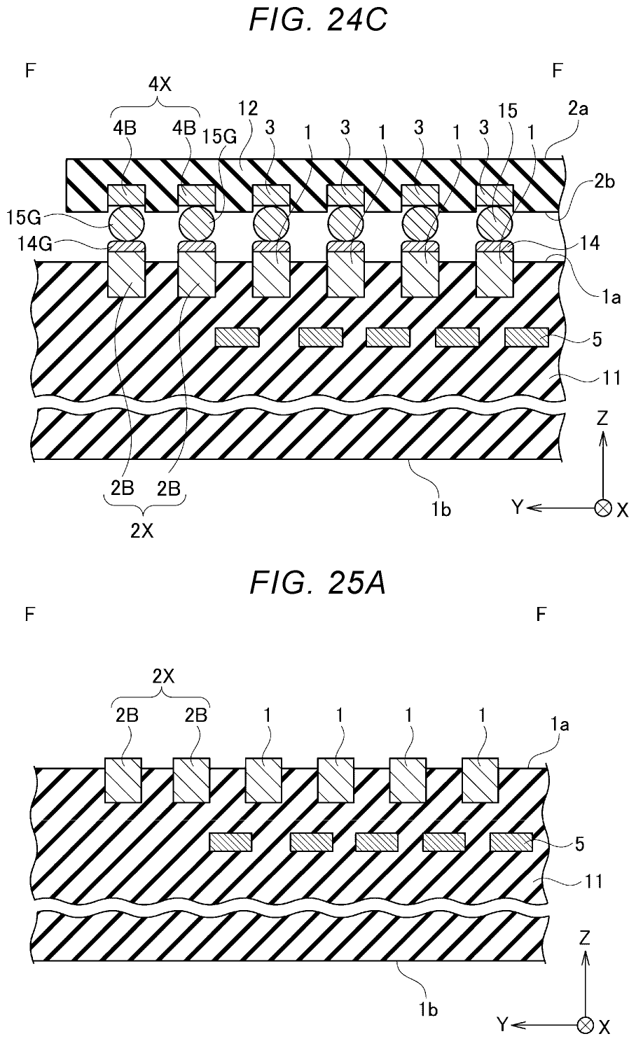

FIGS. 25A to 25D are views showing an example of the method for manufacturing the semiconductor device 40 according to the fourth embodiment.

First, as shown in FIG. 25A, the signal pads 1 and the third non-signal pads 2B are formed on the first main surface 1a of the substrate 11. Specifically, for example, a copper foil is bonded onto the first main surface 1a of the substrate 11, and the substrate 11 is patterned using a resist or the like as a mask member. The patterned mask member is wet etched. The method for forming the signal pads 1 and the third non-signal pads 2B is not limited to the wet etching. Other methods, for example, a plating method may be used.

Next, as shown in FIG. 25B, the solder pastes 14 are applied onto the signal pads 1. The solder pastes 14G are applied onto the third non-signal pads 2B. Specifically, for example, the solder pastes 14 and the solder pastes 14G are printed using a metal mask.

Next, as shown in FIG. 25C, the semiconductor housing portion 12 to be bonded to the substrate 11 is prepared.

Next, as shown in FIG. 25D, the solder balls 15 are formed under the signal pins 3 of the semiconductor housing portion 12, and the solder balls 15G are formed under the second non-signal pins 4B. Specifically, for example, the solder balls 15 and the solder balls 15G are disposed under the signal pins 3 and the second non-signal pins 4B by transferring a mask having holes into which the solder balls 15 and the solder balls 15G fall. As a method for forming the solder balls 15 and the solder balls 15G under the signal pins 3 and the second non-signal pins 4B, other methods may be used.

Finally, the solder balls 15 and the solder balls 15G are connected to the solder pastes 14 and the solder pastes 14G, and the first bonding members 13 and the eighth bonding members 13G are formed. Specifically, the solder pastes 14 are physically connected to the solder balls 15, and the solder pastes 14G are physically connected to the solder balls 15G. Accordingly, as shown in FIG. 24C, the solder pastes 14 and the solder balls 15 are disposed between the signal pads 1 and the signal pins 3. The solder pastes 14G and the solder balls 15G are disposed between the third non-signal pads 2B and the second non-signal pins 4B. Next, the solder pastes 14, the solder balls 15, the solder pastes 14G, and the solder pastes 15G are heated to be melted. Accordingly, as shown in FIG. 23, the solder pastes 14 and the solder balls 15 form the first bonding members 13, and the solder pastes 14G and the solder balls 15G form the eighth bonding members 13G.

According to the above manufacturing method, the semiconductor device 40 according to the fourth embodiment is manufactured.

According to the semiconductor device 40 of the fourth embodiment, an amount of the eighth bonding members 13G per unit area increases, so that the third non-signal pads 2B and the second non-signal pins 4B are firmly bonded.

### Electronic Device

A configuration of an electronic device 100 that includes the semiconductor device 10 according to the embodiment will be described. The semiconductor device 10 of the electronic device 100 may be the semiconductor devices 20, 20A, 20B, 30, 30C, 30D, and 40. Hereinafter, as an example, a case will be described in which the semiconductor device 10 is provided.

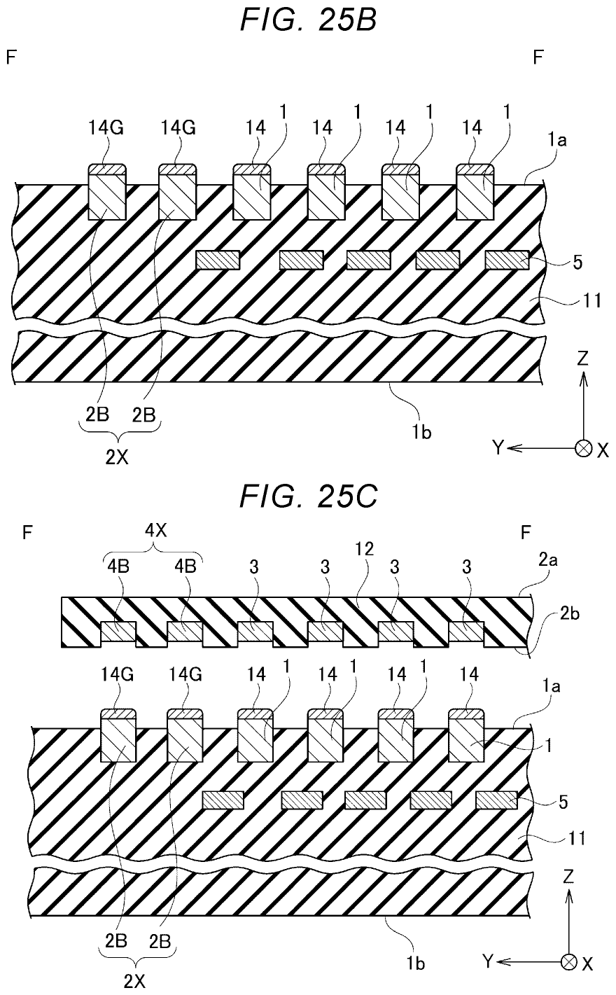

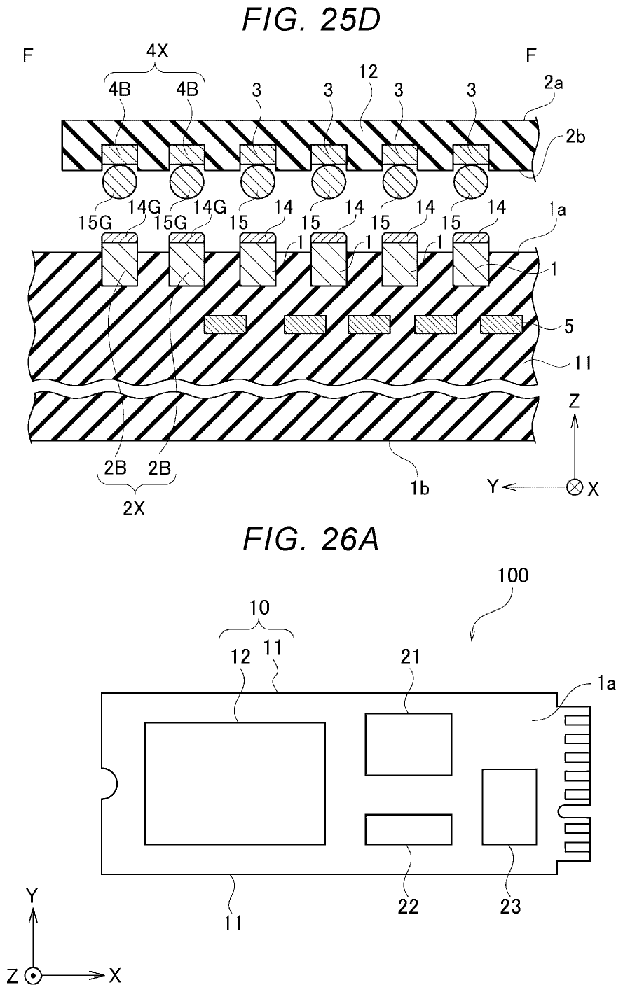

FIG. 26A is a top view of an example of the electronic device 100 that includes the semiconductor device 10 according to the embodiment. FIG. 26B is a bottom view of the example of the electronic device 100 that includes the semiconductor device 10 according to the embodiment. FIG. 27 is a functional block diagram of the electronic device 100. Specifically, the electronic device 100 may be, for example, an M.2-type solid state drive (SSD) that is an example of a storage device.

As shown in FIGS. 26A and 26B, the electronic device 100 includes the semiconductor device 10. The semiconductor device 10 further includes a power supply circuit 21 and a volatile memory 23 on the first main surface 1a of the substrate 11. The semiconductor device 10 further includes a controller 24 on the second main surface 1b of the substrate 11. Note that the semiconductor device 10 may include the controller 24 on the first main surface 1a of the substrate 11. The semiconductor device 10 may further include a capacitor 22.

As shown in FIG. 26A, the semiconductor device 10 includes the semiconductor housing portion 12 on the first main surface 1a of the substrate 11. The semiconductor housing portion 12 houses, for example, NAND type flash memory chips.

As shown in FIG. 26A, the power supply circuit 21, the capacitor 22, and the volatile memory 23 are mounted on the first main surface 1a of the substrate 11. The volatile memory 23 may be, for example, a DRAM. In the following description, the volatile memory 23 is also referred to as a DRAM 23. The capacitor 22 may have a power loss protection (PLP) function.

As shown in FIG. 26B, the controller 24 is mounted on the second main surface 1b of the substrate 11. The controller 24 is an integrated circuit that controls an operation of the entire electronic device 100. The electronic device 100 includes the semiconductor device 10 including the semiconductor housing portion 12. The controller 24 controls the NAND type flash memory chips housed in the semiconductor housing portion 12. The DRAM 23 is used as a temporary memory by the controller 24. The power supply circuit 21 supplies power to the semiconductor device 10, the controller 24, and the DRAM 23.

That is, the semiconductor devices (10, 20, 20A, 20B, 30, 30C, 30D, and 40) according to the first embodiment to the fourth embodiment are applicable for the electronic device 100.

As shown in FIG. 27, the power supply circuit 21 is provided in the electronic device 100. The power supply circuit 21 is connected to the DRAM 23, the controller 24, and the semiconductor housing portion 12 via power supply lines 25 (25a, 25b, and 25c). The power supply circuit 21 supplies a power supply voltage to the DRAM 23 via the power supply line 25a. The power supply circuit 21 supplies a power supply voltage to the controller 24 via the power supply line 25b. The power supply circuit 21 supplies a power supply voltage to the NAND type flash memory chips housed in the semiconductor housing portion 12 via the power supply line 25c, the first non-signal pad 2 of the substrate 11, and the first non-signal pin 4 of the semiconductor housing portion 12.

For example, a plurality of signal lines 26 are provided between the semiconductor housing portion 12 and the controller 24. The NAND type flash memory chips housed in the semiconductor housing portion 12 function as, for example, a storage device of the electronic device 100. The NAND type flash memory chips housed in the semiconductor housing portion 12 exchange signals with the controller 24 via the plurality of signal lines 26, the signal pads 1 of the substrate 11, and the signal pins 3 of the semiconductor housing portion 12. The semiconductor housing portion 12 may be, for example, a multi-chip package that houses a plurality of memory chips.

A signal line 27 is provided between the DRAM 23 and the controller 24. The DRAM 23 temporarily stores, for example, data and the like used in a program execution process in the controller 24, or is used as a work area. The DRAM 23 exchanges a signal with the controller 24 via the signal line 27.

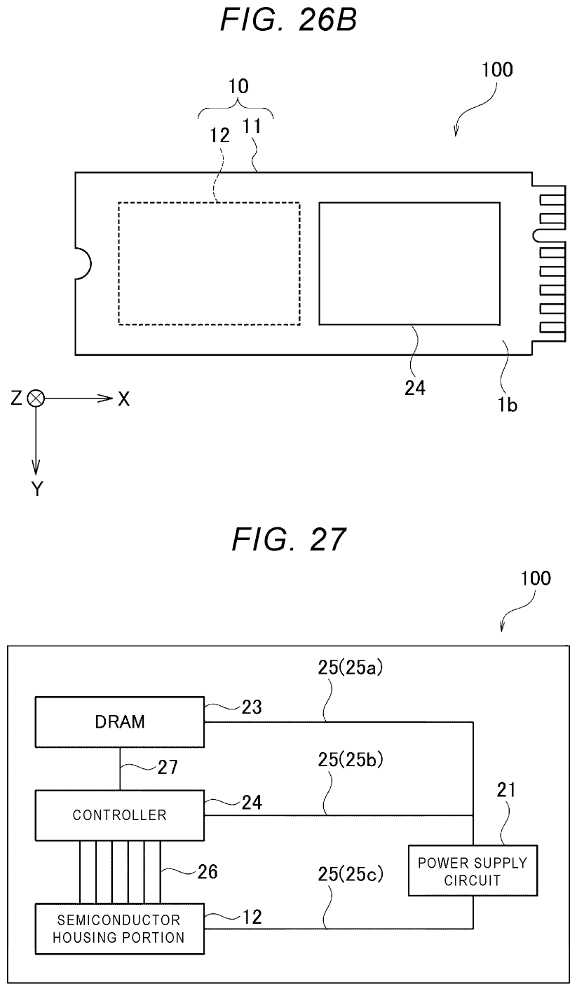

FIG. 28 is a configuration diagram of an electronic device 100A that includes a semiconductor device 10A according to the embodiment. Specifically, the electronic device 100A may be, for example, a desktop or laptop personal computer.

As shown in FIG. 28, the electronic device 100A includes a housing 28A. The housing 28A houses the semiconductor device 10A. The semiconductor device 10A includes a substrate 11A and a semiconductor housing portion 12A. The semiconductor device 10A further includes a controller 24A on the substrate 11A. The semiconductor device 10A may further include a power supply circuit, a capacitor, and a volatile memory (not shown).

That is, the semiconductor devices (10, 20, 20A, 20B, 30, 30C, 30D, and 40) according to the first embodiment to the fourth embodiment are applicable for the electronic device 100A.

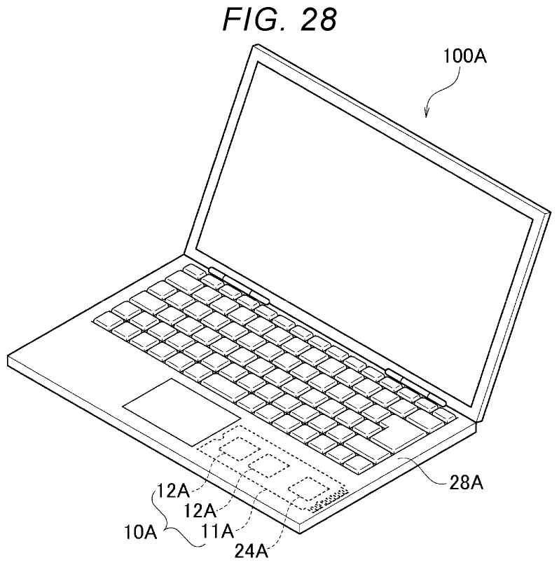

FIG. 29 is a configuration diagram of an electronic device 100B that includes a semiconductor device 10B according to the embodiment. Specifically, the electronic device 100B may be, for example, an SSD.

As shown in FIG. 29, the electronic device 100B includes a housing 28B. The housing 28B houses the semiconductor device 10B. The semiconductor device 10B includes a substrate 11B and a semiconductor housing portion 12B. The semiconductor device 10B further includes a controller 24B, a DRAM 23B, and a power supply circuit 21B.

That is, the semiconductor devices (10, 20, 20A, 20B, 30, 30C, 30D, and 40) according to the first embodiment to the fourth embodiment are applicable for the electronic device 100B.

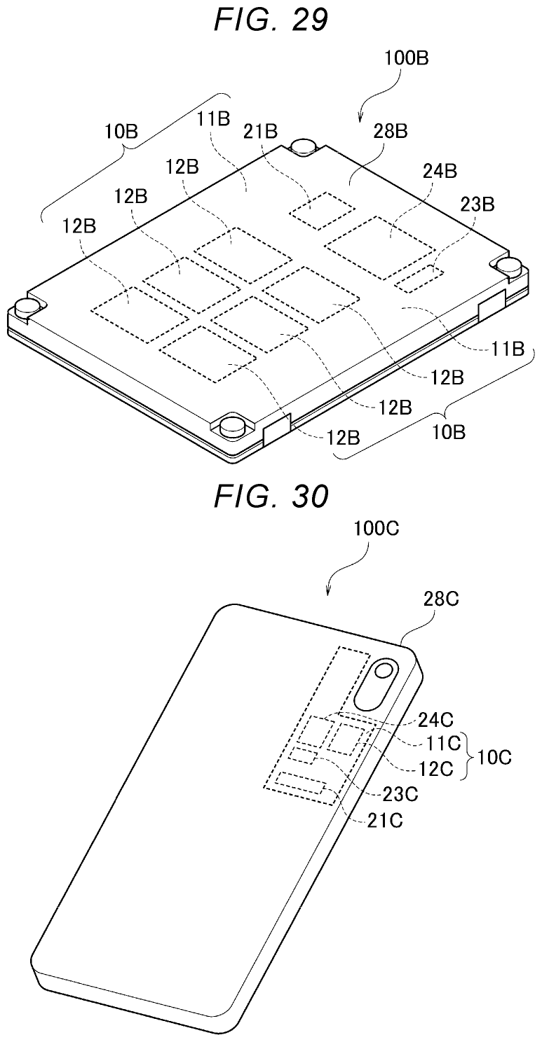

FIG. 30 is a configuration diagram of an electronic device 100C that includes a semiconductor device 10C according to the embodiment. Specifically, the electronic device 100C may be, for example, a smartphone, a tablet, or a mobile terminal. Note that the electronic device 100C is not limited to these examples.

As shown in FIG. 30, the electronic device 100C includes a housing 28C. The housing 28C houses the semiconductor device 10C. The semiconductor device 10C includes a substrate 11C and a semiconductor housing portion 12C. The semiconductor device 10C further includes a controller 24C, a DRAM 23C, and a power supply circuit 21C.

That is, the semiconductor devices (10, 20, 20A, 20B, 30, 30C, 30D, and 40) according to the first embodiment to the fourth embodiment are applicable for the electronic device 100C.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate including a signal pad and at least one first non-signal pad;
a semiconductor housing portion including a signal pin and at least one first non-signal pin; and
first bonding members configured to bond the signal pad and the signal pin and to bond the first non-signal pad and the first non-signal pin, wherein
the first non-signal pad and the first non-signal pin each have an L shape in a plan view.

2. The semiconductor device according to claim 1, wherein
the first non-signal pad and the first non-signal pin are located at one of four corners of an outer periphery of the semiconductor housing portion in the plan view.

3. The semiconductor device according to claim 1, wherein
an area of the first non-signal pad is larger than an area of the signal pad in the plan view, and
an area of the first non-signal pin is larger than an area of the signal pin in the plan view.

4. The semiconductor device according to claim 1, wherein
the signal pad is located inside the semiconductor housing portion with respect to the first non-signal pad in the plan view, and
the signal pin is located inside the semiconductor housing portion with respect to the first non-signal pin in the plan view.

5. The semiconductor device according to claim 1, wherein
a thickness of the first non-signal pad is larger than a thickness of the signal pad in a cross-sectional view.

6. The semiconductor device according to claim 1, wherein
a thickness of the first bonding member on the first non-signal pad is larger than a thickness of the first bonding member on the signal pad in a cross-sectional view.

7. The semiconductor device according to claim 1, wherein
the substrate has a groove, and
the groove is disposed between and separated from the first non-signal pad and the signal pad in the plan view.

8. The semiconductor device according to claim 7, wherein
the groove surrounds an outer periphery of the first non-signal pad in the plan view.

9. The semiconductor device according to claim 1, wherein
the at least one first non-signal pad includes a plurality of first non-signal pads, each one of the plurality of first non-signal pads having a first line width in the plan view,
the at least one first non-signal pin includes a plurality of first non-signal pins, each one of the plurality of first non-signal pins having the first line width in the plan view,
the plurality of first non-signal pads are separated from each other in the plan view, and
the plurality of first non-signal pins are separated from each other in the plan view.

10. The semiconductor device according to claim 1, wherein the substrate includes a multilayer wiring substrate.

11. The semiconductor device according to claim 1, wherein the signal pin includes a signal terminal.

12. The semiconductor device according to claim 1, wherein the signal pad includes a signal terminal.

13. The semiconductor device according to claim 1, wherein the signal pin has a circular shape in the plan view.

14. An electronic device comprising:
the semiconductor device according to claim 1; and
a controller mounted on the substrate, the controller configured to control a semiconductor chip housed in the semiconductor housing portion.

15. A manufacturing method for manufacturing a semiconductor device, the manufacturing method comprising:
forming an L-shaped non-signal pad on a substrate;
forming an L-shaped non-signal pin on a main surface of a semiconductor housing portion facing the substrate;
applying metal pastes onto the non-signal pad and a signal pad of the substrate;
forming metal balls on the non-signal pin and a signal pin of the semiconductor housing portion; and
forming a bonding member that bonds the substrate and the semiconductor housing portion by heating the metal pastes and the metal balls.

16. The manufacturing method according to claim 15, wherein
the metal pastes are solder pastes.

17. The manufacturing method according to claim 15, wherein
the metal balls are solder balls.

18. The manufacturing method according to claim 17, further comprising:
forming a solder ball having a first size on the signal pin; and
forming a plurality of solder balls each having the first size on the non-signal pin.

19. The manufacturing method according to claim 15, wherein a thickness of the non-signal pad is larger than a thickness of the signal pad in a cross-sectional view.

20. The manufacturing method according to claim 19, wherein the signal pad is etched for a longer time than the non-signal pad.
